(19) United States
(12) Patent Application Publication
(10) Pub. No.: US 2008/0248628 A1
(43) Pub. Date: Oct. 9, 2008

(54) Methods of Forming Integrated Circuit Devices Having Single Crystal Semiconductor FIN Structures that Function as Device Active Regions

(75) Inventors: Yong-Hoon Son, Gyeonggi-do (KR); Si-Young Choi, Gyeonggi-do (KR); Jong-Wook Lee, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/056,500

(22) Filed: Mar. 27, 2008

(30) Foreign Application Priority Data
Apr. 9, 2007 (KR) 2007-34550

(51) Int. Cl. H01L 21/3205

(52) U.S. Cl. 438/430; 257/E21.297; 257/E21.303

(57) ABSTRACT

Methods of forming integrated circuit devices include forming an electrically insulating layer having a semiconductor fin structure extending therethrough. This semiconductor fin structure may include at least one amorphous and/or polycrystalline semiconductor region therein. The at least one amorphous and/or polycrystalline semiconductor region within the semiconductor fin structure is then converted into a single crystalline semiconductor region. This semiconductor fin structure is then used as an active region of a semiconductor device.

### REFERENCE TO PRIORITY APPLICATION

This application claims priority under 35 U.S.C. §119 to Korean Patent Application No. 2007-34550, filed Apr. 9, 2007, the disclosure of which is hereby incorporated herein by reference.

### FIELD OF THE INVENTION

The present application relates to methods of forming integrated circuit devices and, more particularly, to methods of forming integrated circuit devices having single crystalline active regions.

### BACKGROUND OF THE INVENTION

As a semiconductor device such as dynamic random access memory (DRAM) device or a nonvolatile memory device becomes more highly integrated, a unit memory cell in the semiconductor device for storing unit information may have a width below about 60 nm. To manufacture such a unit memory cell, processes for forming extremely fine patterns have been developed to provide a semiconductor device having a high integration degree. Considering the high integration degree of the semiconductor device, an isolation region of the semiconductor device may have a reduced width and area, and also an active region thereof may have a decreased width and area because a size of the memory cell may depend on the areas of the active and the isolation regions defined on a substrate. Particularly, the area of the active region may be determined by the isolation region defined by an isolation layer formed on the substrate.

In a conventional method for forming the isolation layer, a pad oxide layer and a nitride layer are formed on a semiconductor substrate, and then a nitride-etching mask is formed on the pad oxide layer by a photolithography process. Using nitride as an etching mask, the pad oxide layer and the substrate are partially etched to form a trench at an upper portion of the substrate. After a silicon oxide layer is formed on the substrate to fill up the trench by a chemical vapor deposition (CVD) process, the silicon oxide layer is planarized to form an isolation layer in the trench. When the nitride-etching mask is removed from the substrate, the isolation layer defines an active region and an isolation region of the substrate.

According to the conventional method, active regions C and isolation regions D are alternately disposed on the semiconductor substrate as illustrated in FIG. 1. Here, each of the active and isolation regions C and D has a width above about 60 nm. However, the widths of the active regions D may not be reduced below about 60 nm since the isolation layer is formed by a photolithography process.

To reduce a size of the active region, a method of forming an isolation region and an active region having widths below about 60 nm using a spacer have been developed. In this method, a self-aligned pattern having a high density is formed on a substrate using the spacer, and then the isolation region is formed by partially etching the substrate using the self-aligned pattern as an etching mask. However, the pattern may be removed before a trench having a relatively deep depth is completed on the substrate in an etching process for forming the deep trench using the pattern. Further, an isolation layer for the isolation region may not completely fill up the deep trench when the trench is filled with silicon oxide to form the isolation layer.

### SUMMARY OF THE INVENTION

Methods of forming integrated circuit devices according to some embodiments of the present invention include forming an electrically insulating layer having a semiconductor fin structure extending therethrough. This semiconductor fin structure may include at least one amorphous and/or polycrystalline semiconductor region therein. The at least one amorphous and/or polycrystalline semiconductor region within the semiconductor fin structure is then converted into a single crystalline semiconductor region. This semiconductor fin structure is then used as an active region of a semiconductor device.

In particular, the converting of the at least one amorphous and/or polycrystalline semiconductor region within the semiconductor fin structure into a single crystalline semiconductor region may include laser annealing the semiconductor fin structure for a sufficient duration to cause the at least one amorphous and/or polycrystalline semiconductor region to undergo a phase transition to a single crystalline material. This phase transition may be an epitaxial phase transition, using an underlying single crystalline semiconductor as a seed. Moreover, this laser annealing may be performed simultaneously with heating the substrate at a temperature in a range from about 200° C. to about 600° C.

According to additional embodiments of the invention, the step of forming an electrically insulating layer having a semiconductor fin structure extending therethrough, includes forming a first electrically insulating layer having an opening therein, on a semiconductor substrate, and then depositing an amorphous (and/or polycrystalline) semiconductor region onto a sidewall of the opening. The opening is then filled with a second electrically insulating layer. The second electrically insulating layer is then planarized for a sufficient duration to expose the first electrically insulating layer and define an amorphous (and/or polycrystalline) semiconductor fin structure from the amorphous (and/or polycrystalline) semiconductor region. The amorphous (and/or polycrystalline) semiconductor fin structure may then be laser annealed for a sufficient duration to cause the amorphous (and/or polycrystalline) semiconductor fin structure to undergo a phase transition to a single crystalline semiconductor fin structure. This laser annealing may be performed while simultaneously heating the semiconductor substrate at a temperature in a range from about 200° C. to about 600° C.

Methods of forming integrated circuit devices according to additional embodiments of the present invention include forming a first electrically insulating layer having at least one opening therein, on a substrate including a semiconductor substrate region thereon. An amorphous semiconductor layer is then deposited onto the first electrically insulating layer and into the opening. The amorphous semiconductor layer is then etched back for a sufficient duration to define an amorphous semiconductor spacer on a sidewall of the opening. A second electrically insulating layer is then deposited onto the first electrically insulating layer and into the opening. The second electrically insulating layer is planarized for a sufficient duration to expose the first electrically insulating layer and convert the amorphous semiconductor spacer into an upright amorphous semiconductor structure. A laser-annealing step is then performed to convert the upright amorphous semiconductor structure into an upright single crystalline semiconductor structure.

According to additional aspects of these embodiments of the invention, the at least one opening may expose the semiconductor substrate region. In this case, the upright single crystalline semiconductor structure is electrically connected to the semiconductor substrate region. The amorphous semiconductor layer may be formed of a material selected from a group consisting of silicon, germanium and silicon-germanium.

Still further embodiments of the present invention include forming an electrically insulating layer having an amorphous semiconductor fin extending therethrough, on a single crystalline semiconductor region that contacts a bottom of the amorphous semiconductor fin. The amorphous semiconductor fin is converted (e.g., by laser annealing) into a single crystalline semiconductor fin using an epitaxial phase transition process that includes laser annealing the amorphous semiconductor fin. A semiconductor device is then formed, which utilizes the single crystalline semiconductor fin as an active region. In particular, the semiconductor device may be an EEPROM transistor, which includes a floating gate electrode that is formed on the single crystalline semiconductor fin.

### BRIEF DESCRIPTION OF THE DRAWINGS

The above and other features and advantages of the invention will become readily apparent by reference to the following detailed description when considered in conjunction with the accompanying drawings wherein:

FIG. 1 is a plan view illustrating a substrate having an active region and an isolation region formed through a conventional method;

FIGS. 2A to 2E are cross-sectional views illustrating a method of manufacturing a semiconductor memory device in accordance with example embodiments of the present invention;

FIGS. 3A to 3E are plan views illustrating a method of manufacturing a semiconductor memory device in accordance with example embodiments of the present invention;

FIGS. 4A to 4F are cross-sectional views illustrating a method of manufacturing a semiconductor memory device in accordance with example embodiments of the present invention; and

FIGS. 5A to 5B are plan views illustrating a method of manufacturing a semiconductor memory device in accordance with example embodiments of the present invention.

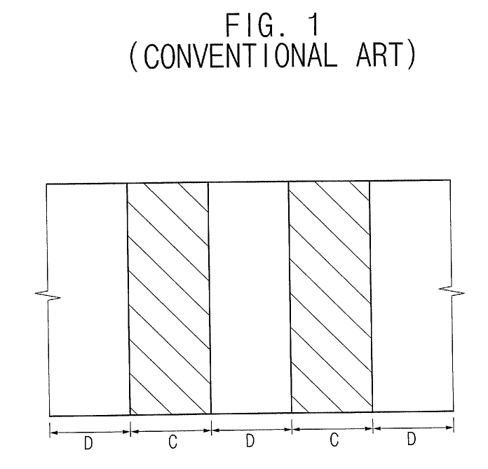

### DESCRIPTION OF THE EMBODIMENTS

The present invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof. Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

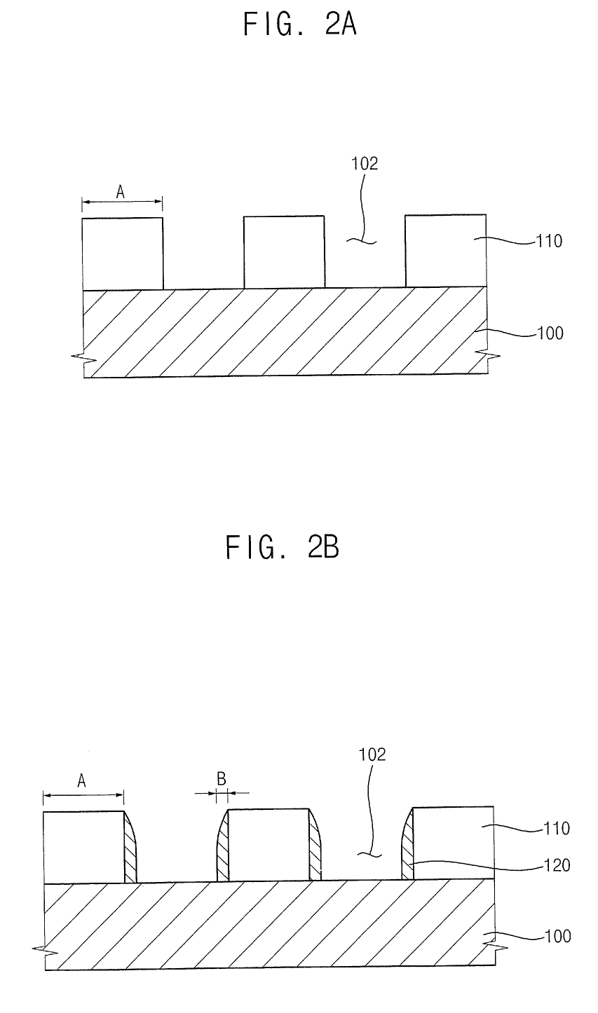

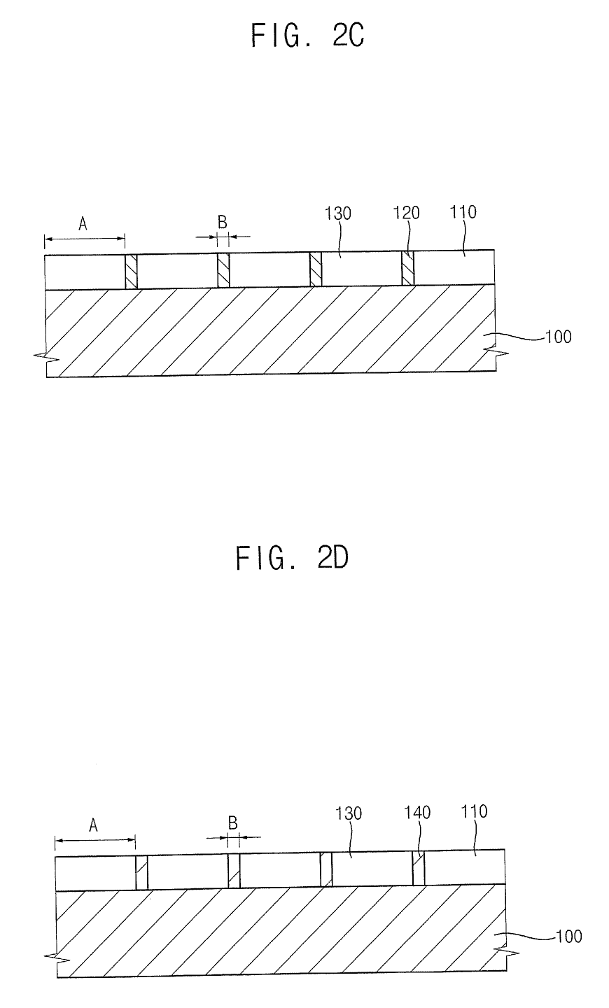

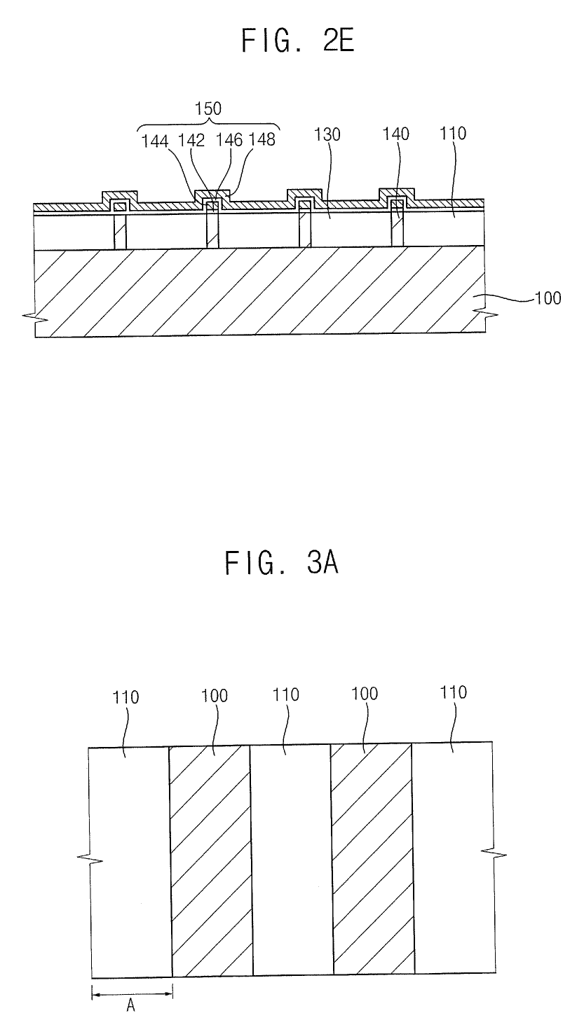

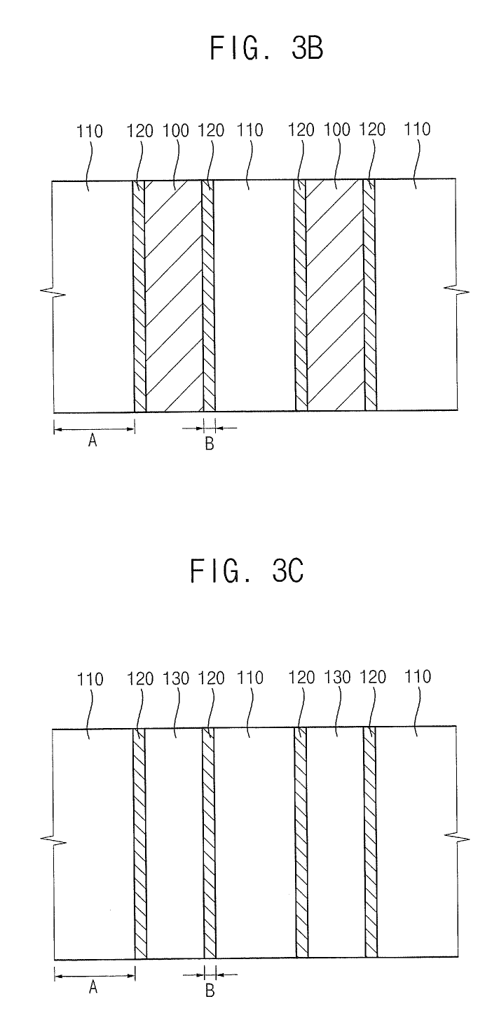

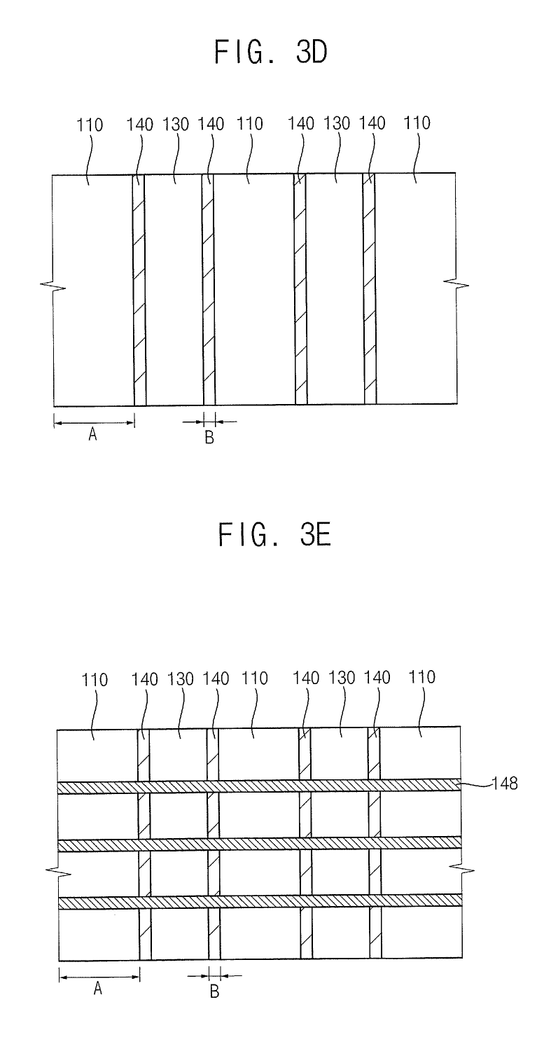

FIGS. 2A to 2E are cross-sectional views illustrating a method of manufacturing a semiconductor memory device in accordance with example embodiments of the present invention. FIGS. 3A to 3E are plan views illustrating the method of manufacturing the semiconductor memory device in accordance with example embodiments of the present invention.

Referring to FIGS. 2A and 3A, a substrate 100 is provided. The substrate 100 may include a single crystalline material. For example, the substrate 100 may include single crystalline silicon, single crystalline germanium. Alternatively, the substrate 100 may include silicon-germanium. In example embodiments, the substrate 100 may include a single crystalline layer formed from an amorphous layer through a phase transition of the amorphous layer. In one example embodiment, the substrate 100 may include a single crystalline silicon substrate.

First insulation layer patterns 110 are formed on the substrate 100. A trench 102 is provided between adjacent first insulation layer patterns 110 in accordance with formation of the first insulation layer patterns 110. In the formation of the first insulation layer patterns 110, a first insulation layer (not illustrated) may be formed on the substrate 100. The first insulation layer may be formed using boro-phosphor silicate glass (BPSG), phosphor silicate glass (PSG), undoped silicate glass (USG), sfin on glass (SOG), flowable oxide (FOX), plasma enhanced-tetraethylorthosilicate (PE-TEOS), high density plasma-chemical vapor deposition (HDP-CVD) oxide, etc. Further, the first insulation layer may be formed on the substrate 100 by a chemical vapor deposition (CVD) process, a plasma enhanced-chemical vapor deposition (PE-CVD) process, a low pressure chemical vapor deposition (LPCVD) process, a high density plasma-chemical vapor deposition (HDP-CVD) process, etc.

An etching mask (not illustrated) may be formed on the first insulation layer. The etching mask may define an isolation layer of the semiconductor memory device. The etching mask may have a width of about 50 nm to about 80 nm. In one example embodiment, the etching mask may have a width of about 55 nm to about 70 nm.

The first insulation layer may be partially etched using the etching mask to form the first insulation layer patterns 110 and the trench 102 on the substrate 100. The trench 102 may partially expose an upper face of the substrate 100. The trench 102 may have a width substantially wider than a width of each of the first insulation layer patterns 110. The etching mask may be removed from the first insulation layer pattern 110 by a wet etching process and/or a dry etching process.

In example embodiments, each of the first insulation layer patterns 110 may have width A of about 50 nm to about 80 nm. For example, the width A of the first insulation layer pattern 110 may be in a range of about 55 nm to about 70 nm. In one example embodiment, the first insulation layer pattern 110 may have the width A of about 60 nm.

Referring to FIGS. 2B and 3B, a spacer 120 is formed on a sidewall of each of the first insulation layer pattern 110. That is, the spacer 120 is formed on an inner sidewall of the trench 102. In formation of the spacer 120, an amorphous layer (not illustrated) may be formed on the exposed portion of the substrate 100 and on the first insulation layer patterns 110. The amorphous layer may have a uniform thickness based on the exposed portion of the substrate 100, the sidewalls of the first insulation layer patterns 110 and upper faces of the first insulation layer patterns 110.

In example embodiments, the amorphous layer may have a thickness substantially the same or substantially similar to that of a fin 140 (see FIGS. 2D and 3D) corresponding to an active region of the semiconductor memory device. The amorphous layer may be formed using an amorphous material such as amorphous silicon, amorphous germanium, polysilicon, etc.

When the substrate 100 includes single crystalline germanium, the amorphous layer may include amorphous germanium. When the substrate 100 includes single crystalline silicon-germanium, the amorphous layer may also include amorphous silicon-germanium. In one example embodiment, the amorphous layer may include amorphous silicon when the substrate 100 includes the single crystalline silicon substrate. In example embodiments, the amorphous layer may formed by a CVD process. The amorphous layer may have a thin thickness, however, the thickness of the amorphous layer may vary in accordance with a construction of the semiconductor memory device.

The amorphous layer may be etched until the substrate 100 is exposed. The amorphous layer may be etched by an anisotropic etching process. For example, the amorphous layer may be etched by an anisotropic dry etching process using a plasma. As a result, the spacer 120 is formed on the sidewall of the first insulation layer pattern 110.

In some example embodiments, a ratio between a width B of the spacer 120 and the width A of the first insulation layer pattern 110 may be in a range of about 1:2 to about 1:4. For example, when the spacer 120 has the width B of about 15 nm to about 30 nm, the first insulation layer pattern 110 may have the width A of about 50 nm to about 80 nm. In one example embodiment, the width B of the spacer 120 may be about 20 nm.

Referring to FIGS. 2C and 3C, a second insulation layer pattern 130 is formed in the trench 102 between adjacent first insulation layer patterns 110. The second insulation layer pattern 130 may fill up the trench 102. In example embodiments, a second insulation layer (not illustrated) may be formed on the first insulation layer patterns 110 to fill up the trench 102. The second insulation layer may be formed using a material substantially the same as that of the first insulation layer. For example, the second insulation layer may be formed using silicon oxide.

The second insulation layer may be partially removed by a planarization process to form the second insulation layer pattern 130. Here, the first insulation layer patterns 110 and the spacer 120 may be partially removed. Thus, the second insulation layer may have a width substantially the same as those of the first insulation layer patterns 110 and that of the spacer 120. The second insulation layer may be planarized by a chemical mechanical polishing (CMP) process using a slurry that includes ceria as an abrasive. The second insulation layer pattern 130 may be positioned between adjacent first insulation layer patterns 110. Particularly, the second insulation layer pattern 130 may locate between adjacent spacers 120 formed on the sidewalls of the first insulation layer patterns 110.

Referring to FIGS. 2D and 3D, the fin 140 is formed from the spacer 120. That is, the spacer 120 having the amorphous structure may be changed into the fin 140 having a crystalline structure by an epitaxial phase transition process. For example, the fin 140 may be formed by the epitaxial phase transition of the spacer 120 using the substrate 100 including the single crystalline material as a seed. In the phase transition process, a laser beam may be irradiated onto the spacer 120 having a solid phase to melt the spacer 120, and then the spacer 120 having a liquid phase may be changed into the fin 140 having the crystalline structure in accordance with the crystalline structure of the substrate 100. Namely, the fin 140 maybe formed from the spacer 120 by melting the spacer 120 and the epitaxial phase transition process. When the spacer 120 is melted by a heat treatment process using a furnace, the heat treatment process may be performed at a relatively high temperature so that a thermal stress may be caused in the substrate 100 and the resultant structure on the substrate 100. Further, the spacer 120 may not be locally melted by the heat treatment process. Hence, the spacer 120 may be advantageously melted using the laser beam to properly form the fin 140 on the substrate 100.

In example embodiments, the spacer 120 having the amorphous structure may be changed into the fin 140 having the single crystalline structure since the single crystalline material in the substrate 100 serves as the seed in the epitaxial phase transition process. For example, the fin 140 may have the single crystalline structure grown along a direction substantially perpendicular to the substrate 100.

In example embodiments, the laser beam may be irradiated onto the spacer 120 with a sufficient energy to entirely melt the spacer 120 because the laser beam may melt entire portion of the spacer 120 from an upper portion of the spacer 120 to a bottom portion of the spacer 120 contacting the substrate 100. The laser beam may have an energy varied in accordance with the width and the height of the spacer 120. Although the laser beam may have various energy levels, the laser beam may advantageously have an energy for providing a temperature above about 1,140° C. when the spacer 120 includes amorphous silicon since a melting point of silicon is about 1,410° C. Further, the phase transition of the spacer 120 may be carried out for a time of about several nanoseconds to about several tens of nanoseconds so that the fin 140 may not have any defect therein.

In example embodiments, the substrate 100 may be heated while changing the spacer 120 into the fin 140. That is, a heat treatment process may be performed about the substrate 100 to reduce a temperature gradient of the spacer 120. Thus, the fin 140 having the single crystalline structure may include relatively large grains when the spacer 120 is changed into the fin 140. When the substrate 100 is heated at a temperature below about 200° C., the grains of the fin 140 may not grow beyond predetermined sizes. When the substrate 100 is heated at a temperature above about 600° C., the substrate 100 and/or the resultant structure may be damaged while changing the spacer 120 into the fin 140. Therefore, the heat treatment process may be executed about the substrate 100 at a temperature of about 200° C. to about 600° C. In one example embodiment, the substrate 100 may be heated at a temperature of about 350° C. to about 450° C.

As described above, the laser beam may be irradiated onto the spacer 120 having the amorphous structure to form the fin 140 having the single crystalline structure. The fin 140 may correspond to the active region of a semiconductor memory device. Here, the first and the second insulation layer patterns 110 and 130 may correspond to an isolation region of the semiconductor memory device.

In some example embodiments, a planarization process may be additionally performed about the fin 140, the first insulation layer patterns 110 and the second insulation layer pattern 130. Thus, the fin 140, the first insulation layer patterns 110 and the second insulation layer pattern 130 may have substantially the same heights. For example, the fin 140, the first insulation layer patterns 110 and the second insulation layer pattern 130 may be planarized by a CMP process.

Referring to FIGS. 2E and 3E, a gate structure 150 is formed on the resultant structure having the fin 140. The gate structure 150 includes a tunnel insulation layer pattern 142, a floating gate 144, a dielectric layer pattern 146 and a control gate 148 when the gate structure 150 is employed in a memory cell of a nonvolatile semiconductor memory device.

In formation of the gate structure 150, a tunnel insulation layer (not illustrated) may be formed on the fin 140. The tunnel insulation layer (not illustrated) may be formed using silicon oxide, metal oxide or metal compound. A preliminary floating gate (not illustrated) may be formed on the tunnel insulation layer and the first and the second insulation layer patterns 110 and 120. The preliminary floating gate may be formed using doped polysilicon, metal or metal compound. A dielectric layer (not illustrated) may be formed on the preliminary floating gate. In example embodiments, the dielectric layer may have a structure that includes a lower oxide film, a nitride film and an upper oxide film (e.g., an ONO structure). Alternatively, the dielectric layer may be formed using a high-k material such as a metal and/or a metal compound. Examples of the metal and the metal compound in the dielectric layer may include tungsten (W), aluminum (Al), titanium (Ti), hafnium oxide (HfOx), zirconium oxide (ZrOx), tantalum oxide (TaOx), yttrium oxide (YOx), niobium oxide (NbOx), aluminum oxide (AlOx), titanium oxide (TiOx), cerium oxide (CeOx), indium oxide (InOx), ruthenium oxide (RuOx), magnesium oxide (MgOx), strontium oxide (SrOx), boron oxide (BOx), lead oxide (PbOx), vanadium oxide (VOx), lanthanum oxide (LaOx), praseodymium oxide (PrOx), stibium oxide (SbOx), calcium oxide (CaOx), etc. These may be used alone or in a mixture thereof. The dielectric layer may include a silicon oxide film, a silicon nitride film, a metal compound film successively stacked on the preliminary floating gate. Alternatively, the dielectric layer may include a lower metal oxide film, a silicon nitride film and an upper metal oxide film. Here, the metal oxide film or the metal compound film may be formed by a CVD process or an ALD process using a metal precursor.

A preliminary control gate (not illustrated) is formed on the dielectric layer. The preliminary control gate may be formed using doped polysilicon, a metal and/or a metal compound. Examples of the metal and the metal compound in the preliminary control gate may include tungsten, aluminum, titanium, tungsten silicide (WSix), cobalt silicide (CoSix), titanium silicide (TiSix), tantalum silicide (TaSix), etc. In example embodiments, the preliminary control gate may include a polysilicon film doped with N⁺ type impurities and/or a metal silicide film.

A mask pattern (not illustrated) may be formed on the preliminary control gate. The mask pattern may define a region where the gate structure 150 is formed. For example, the mask pattern may have a line shape extending along a second direction substantially perpendicular to a first direction in which the isolation layer extends.

The preliminary control gate, the dielectric layer, the preliminary floating gate and the tunnel insulation layer may be partially etched using the mask pattern as an etching mask. Thus, the gate structure 150 may be provided on the fin 140 and the isolation layer. As described above, the gate structure 150 includes the tunnel insulation layer pattern 142, the floating gate 144, the dielectric layer pattern 146 and the control gate 148 when the gate structure 150 is employed in the memory cell of the nonvolatile semiconductor memory device.

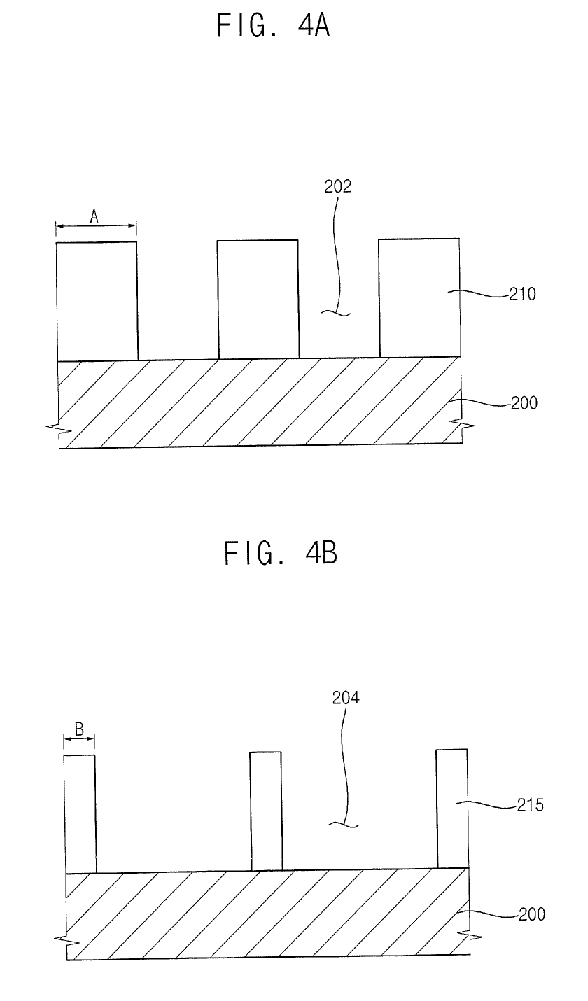

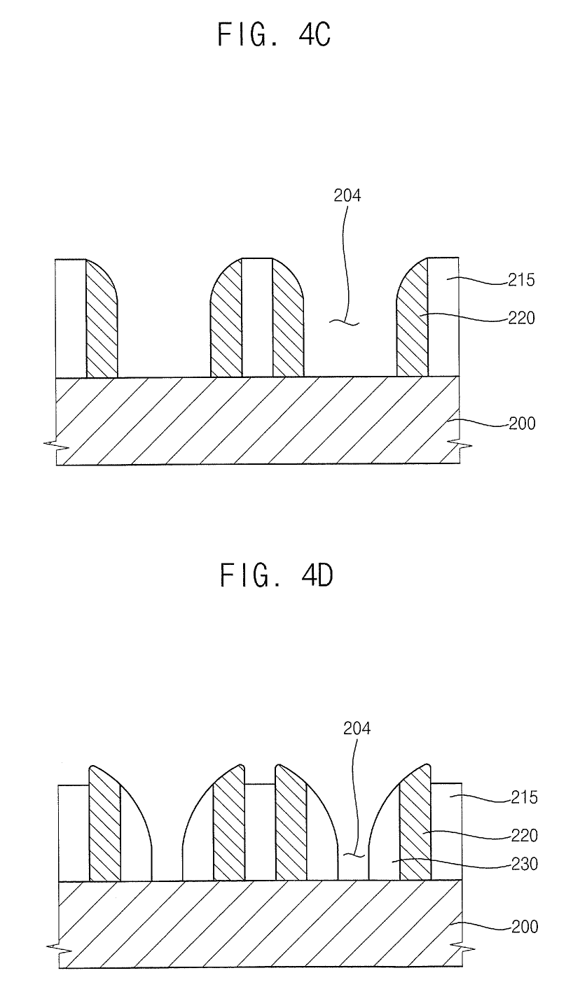

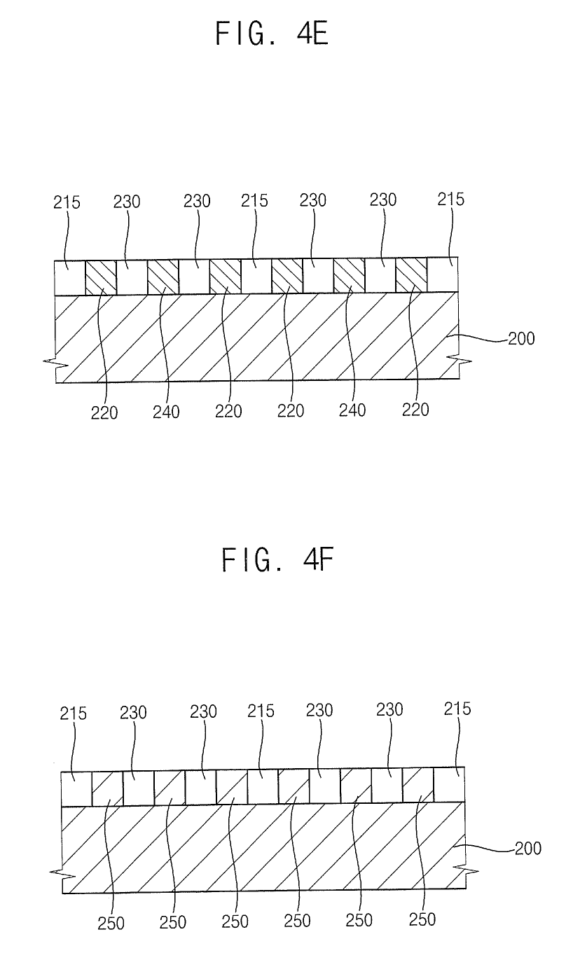

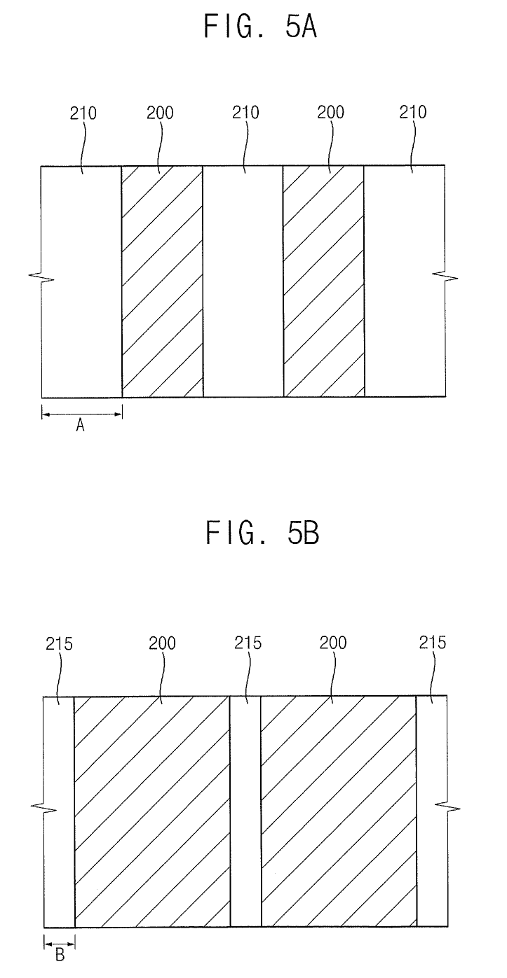

FIGS. 4A to 4F are cross-sectional views illustrating a method of manufacturing a semiconductor memory device in accordance with example embodiments of the present invention. FIGS. 5A to 5B are plan views illustrating the method of manufacturing the semiconductor memory device in accordance with example embodiments of the present invention.

Referring to FIGS. 4A and 5A, a first insulation layer pattern 210 and a first trench 202 are provided on a substrate 200 including a single crystalline material. The first insulation layer pattern 210 and the first trench 202 may be formed by processes substantially the same or substantially similar to those described with reference to FIGS. 2A to 3A. The first insulation layer pattern 210 may have a first width A substantially the same as a width of the first trench 202. For example, the first insulation layer pattern 210 may have the first width of about 60 nm.

Referring to FIGS. 4B and 5B, a second insulation layer pattern 215 is formed by etching a sidewall of the first insulation layer pattern 210. The second insulation layer pattern 215 may be formed by an isotropic etching process using an etching solution that includes a hydrogen fluoride solution. While forming the second insulation layer pattern 215, a second trench 204 is provided because the second insulation layer pattern 215 is formed by etching an inner sidewall of the first trench 202. The second insulation layer pattern 215 has a second width B smaller than the first width A of the first insulation layer pattern 210.

In example embodiments, the second insulation layer pattern 215 may have the second width B narrower than the first width A of the first insulation layer pattern 210 and the width of the first trench 202. A ratio between the first width A and the second width B may be about 3:1. For example, the second width B may be about 20 nm when the first width A is about 60 nm.

Since the second trench 204 is formed by etching the sidewall of the first trench 202, the second trench 204 may have a width substantially larger than the width of the first trench 202. In example embodiments, a ratio between the width of the first trench 202 and the width of the second trench 204 may be in a range of about 1:4 to about 1:6. For example, the ratio between the width of the first trench 202 and the width of the second trench 204 may be about 1:3.

Referring to FIG. 4C, a first spacer 220 is formed on a sidewall of the second insulation layer pattern 215. The first spacer 220 may be formed using an amorphous material such as amorphous silicon. The first spacer 220 may be formed by a process substantially the same as or substantially similar to the process described with reference to FIGS. 2B and 3B.

In example embodiments, the first spacer 220 may have a width substantially the same as the second width B of the second insulation layer pattern 215. For example, the first spacer 220 may have a width of about 15 nm to about 30 nm when the second insulation layer pattern 215 has the second width of about 15 nm to about 30 nm. In one example embodiment, the first spacer 220 may have a width of about 20 nm.

Referring to FIG. 4D, a second spacer 230 is formed on the first spacer 220. The second spacer 230 may be formed using a material substantially the same or substantially similar to that of the second insulation layer pattern 215. For example, the second spacer 230 may be formed using silicon oxide when the second insulation layer pattern 215 includes silicon oxide. Thus, the second insulation layer pattern 215 may be partially etched while forming the second spacer 230. In other words, a recess or a dent may be generated at an upper portion of the second insulation layer pattern 215. The second spacer 230 may be formed by a process substantially the same as or substantially similar to the process for forming the first spacer 220.

In example embodiments, the second spacer 230 may have a width substantially the same as the width of the first spacer 220. When the first spacer 220 has the width of about 15 nm to about 30 nm, the second spacer 230 may also have a width of about 15 nm to about 30 nm.

Referring to FIG. 4E, an amorphous layer pattern 240 is formed in the second trench 204 after forming the second spacer 230.

In example embodiments, an amorphous layer (not illustrated) may be formed on the second insulation layer pattern 215, the first spacer 220 and the second spacer 230 to fill up the second trench 204. The amorphous layer may be formed using a material substantially the same or substantially similar to that of the first spacer 220. The amorphous layer may be partially removed by a planarization process. Here, upper portions of the second insulation layer pattern 215, the first spacer 220 and the second spacer 230 may be partially removed. Thus, the amorphous pattern 240 may be formed in the second trench 204 between adjacent second spacers 230.

Referring to FIG. 4F, a single crystalline fin 250 is formed from the first spacer 220 and the amorphous layer pattern 240 by an epitaxial phase transition process. The single crystalline fin 250 may be formed by a process substantially the same as the process described with reference to FIGS. 2D and 3D.

In example embodiments, the single crystalline fin 250 may be formed form the first spacer 220 and the amorphous layer pattern 240 using the substrate 200 including the single crystalline material as a seed. In the epitaxial phase transition process, the first spacer 220 and the amorphous layer pattern 240 may be melted, and then the single crystalline fin 250 may be formed from the first spacer 220 and the amorphous layer pattern 240 having liquid phases. The first spacer 220 and the amorphous layer pattern 240 may be melted by irradiating a laser beam thereto. The single crystalline fin 250 may correspond to an active region of the semiconductor memory device. Here, the second insulation layer pattern 215 and the second spacer 240 may serve as an isolation layer to provide an isolation region of the semiconductor substrate.

In example embodiments, a planarization process may be additionally performed about the single crystalline fin 250, the second insulation layer pattern 215 and the second spacer 240 after formation of the single crystalline fin 250. Thus, the single crystalline fin 250, the second insulation layer pattern 215 and the second spacer 240 may have substantially same heights. The single crystalline fin 250, the second insulation layer pattern 215 and the second spacer 240 may be planarized by a CMP process.

A gate structure (not illustrated) may be formed on the resultant structure including the single crystalline fin 250. The gate structure may include a tunnel insulation layer pattern, a floating gate, a dielectric layer pattern and a control gate when the gate structure is employed in a memory cell of a nonvolatile semiconductor memory device. The gate structure may be formed by processes substantially the same as or substantially similar to those described with reference to FIGS. 2E and 3E.

According to example embodiments of the invention, a single crystalline fin serving as an active region of a semiconductor device may be obtained by an epitaxial phase transition process using a substrate as a seed. The single crystalline fin may be formed from an insulation layer pattern and/or a spacer adjacent to an isolation region of the semiconductor substrate. Since the single crystalline fin may have a small width adjusted by a width of the spacer and or the insulation layer pattern, the active region of the semiconductor device may have an extremely small width below about 40 nm. When the semiconductor device includes the active region narrower than that of the conventional semiconductor device by more than twice, the semiconductor device may have a very high integration degree to ensure an improved reliability. Further, the active region (the single crystalline fin) of the semiconductor device may be formed after formation of an isolation layer, so that generation of a void in the isolation layer may be effectively prevented.

The foregoing is illustrative of the present invention and is not to be construed as limiting thereof. Although a few example embodiments of the invention have been described, those skilled in the art will readily appreciate that many modifications are possible in the example embodiments without materially departing from the novel teaching and advantages of this invention. Accordingly, all such modifications are intended to be included within the scope of the present inventions as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

1. A method of forming an integrated circuit device, comprising:
forming an electrically insulating layer having a semiconductor fin structure extending therethrough, said semiconductor fin structure comprising at least one amorphous and/or polycrystalline semiconductor region therein;
converting the at least one amorphous and/or polycrystalline semiconductor region in the semiconductor fin structure into a single crystalline semiconductor region; and
forming a semiconductor device that utilizes the semiconductor fin structure as an active region of the semiconductor device.

2. The method of claim 1, wherein said converting comprises laser annealing the semiconductor fin structure for a sufficient duration to cause the at least one amorphous and/or polycrystalline semiconductor region to undergo a phase transition to a single crystalline material.

3. The method of claim 2, wherein forming an electrically insulating layer comprises forming an electrically insulating layer on a substrate; and wherein said converting comprises laser annealing the semiconductor fin structure while simultaneously heating the substrate at a temperature in a range from about 200° C. to about 600° C.

4. The method of claim 1, wherein the semiconductor device is a non-volatile memory cell; and wherein forming a semiconductor device comprises forming a floating gate electrode on the semiconductor fin structure.

5. The method of claim 1, wherein forming an electrically insulating layer having a semiconductor fin structure extending therethrough, comprises:
forming a first electrically insulating layer having an opening therein, on a semiconductor substrate;
depositing an amorphous semiconductor region onto a sidewall of the opening;
filling the opening with a second electrically insulating layer; and
planarizing the second electrically insulating layer for a sufficient duration to expose the first electrically insulating layer and define an amorphous semiconductor fin structure from the amorphous semiconductor region.

6. The method of claim 5, wherein said converting comprises laser annealing the amorphous semiconductor fin structure for a sufficient duration to cause the amorphous semiconductor fin structure to undergo a phase transition to a single crystalline semiconductor fin structure.

7. The method of claim 6, wherein said converting comprises laser annealing the amorphous semiconductor fin structure while simultaneously heating the semiconductor substrate at a temperature in a range from about 200° C. to about 600° C.

8. The method of claim 1, wherein forming an electrically insulating layer having a semiconductor fin structure extending therethrough, comprises:
forming a first electrically insulating layer having an opening therein, on a semiconductor substrate;
depositing a polycrystalline semiconductor region onto a sidewall of the opening;
filling the opening with a second electrically insulating layer;
planarizing the second electrically insulating layer for a sufficient duration to expose the first electrically insulating layer and define a polycrystalline semiconductor fin structure from the polycrystalline semiconductor region.

9. The method of claim 8, wherein said converting comprises laser annealing the semiconductor fin structure for a sufficient duration to cause the polycrystalline semiconductor fin structure to undergo a phase transition to a single crystalline semiconductor fin structure.

10. The method of claim 9, wherein said converting comprises laser annealing the semiconductor fin structure while simultaneously heating the semiconductor substrate at a temperature in a range from about 200° C. to about 600° C.

11. A method of forming an integrated circuit device, comprising:
forming a first electrically insulating layer having at least one opening therein, on a substrate comprising a semiconductor substrate region thereon;
depositing an amorphous semiconductor layer onto the first electrically insulating layer and into the opening;
etching back the amorphous semiconductor layer for a sufficient duration to define an amorphous semiconductor spacer on a sidewall of the opening;
depositing a second electrically insulating layer onto the first electrically insulating layer and into the opening;
planarizing the second electrically insulating layer for a sufficient duration to expose the first electrically insulating layer and convert the amorphous semiconductor spacer into an upright amorphous semiconductor structure; and
laser annealing the upright amorphous semiconductor structure to convert it to an upright single crystalline semiconductor structure.

12. The method of claim 11, wherein the at least one opening exposes the semiconductor substrate region; and wherein the upright single crystalline semiconductor structure is electrically connected to the semiconductor substrate region.

13. The method of claim 12, wherein the amorphous semiconductor layer comprises a semiconductor material selected from a group consisting of silicon, germanium and silicon-germanium.

14. The method of claim 11, wherein laser annealing comprises laser annealing the upright amorphous semiconductor structure while simultaneously heating the substrate at a temperature in a range from about 200° C. to about 600° C.

15. A method of forming an integrated circuit device, comprising:
forming an electrically insulating layer having an amorphous semiconductor fin extending therethrough, on a single crystal semiconductor region that contacts a bottom of the amorphous semiconductor fin;
converting the amorphous semiconductor fin into a single crystalline semiconductor fin using an epitaxial phase transition process that includes laser annealing the amorphous semiconductor fin; and
forming a semiconductor device that utilizes the single crystalline semiconductor fin as an active region of the semiconductor device.

16. The method of claim 15, further comprising:
forming a floating gate electrode of an EEPROM transistor on the single crystalline semiconductor fin.

17. The method of claim 15, wherein said converting comprises laser annealing the amorphous semiconductor fin while simultaneously heating the single crystalline semiconductor region at a temperature in a range from about 200° C. to about 600° C.

18.-37. (canceled)
